(19) United States
(12) Patent Application Publication
(10) Pub. No.: US 2012/0308779 A1
(43) Pub. Date: Dec. 6, 2012

(54) MEMBRANE FOR OXYGEN GENERATION

(75) Inventors: Mareike Klee, Eindhoven (NL); Ruediger Mauczok, Eindhoven (NL); Rainer Hilbig, Eindhoven (NL); Wilhelmus Cornelis Keur, Eindhoven (NL)

(73) Assignee: KONINKLIJKE PHILIPS ELECTRONICS N.V., EINDHOVEN (NL)

(21) Appl. No.: 13/574,799

(22) PCT Filed: Jan. 28, 2011
(86) PCT No.: PCT/IB2011/050382

§ 371 Date: Jul. 24, 2012

(30) Foreign Application Priority Data
Feb. 3, 2010 (EP) 10152542.6
Oct. 22, 2010 (EP) 10188464.1

(51) Int. Cl. B32B 3/30; B81C 1/00; B23P 17/00; B24C 1/00

(52) U.S. Cl. 428/158; 451/38; 29/557; 29/527.2

(57) ABSTRACT

The invention relates to a membrane system which is particular suitable for oxygen generation. It comprises a membrane (14), and a porous substrate (12) for supporting the membrane (14), wherein the substrate (12) comprises pillars (15) and defined channels (16) for bringing a gas in controlled contact with the membrane (14). This membrane system (10) allows a gas flux and is furthermore applicable for small and light devices.

### FIELD OF THE INVENTION

The invention relates to the field of membrane systems. More particularly, the invention relates to mobile oxygen gas generation for applications such as medical applications or chemical reactions using membranes.

### BACKGROUND OF THE INVENTION

Oxygen generation using membranes plays an important role in different application areas, covering for example the generation of high purity oxygen, and partial oxidation reactions of hydrocarbons in membrane reactors. The production of high purity oxygen is also of particular interest for small, low noise oxygen generators for medical applications such as home healthcare applications. Innovative solutions for this application make use of oxygen membranes that take care of a sufficient oxygen flux through the membranes.

Dense ceramic materials exhibiting mixed ionic electronic conductivity can be used as membrane materials for the production of oxygen. In J. F. Vente et al., J. Membrane Sci., 276 (2006), 178-184, functional perovskite membranes with a thickness of approximately 200 μm are disclosed, as well as 6 μm thick dense layers on 200 μm thick porous supports. The paper discusses the influence of composition, and thickness of porous activation layers and measurement conditions on the oxygen permeation rates. The highest oxygen fluxes under non-reducing conditions were approximately 13 N ml cm⁻²min⁻¹.

The major drawback of the ceramic membrane systems disclosed in Vente et al. is the limited oxygen flux. If the bulk transport through the membrane is the rate determining step, the oxygen flux, J, is governed by the Wagner relation, as described in C. Wagner, Z, Phys. Chem., B21 (1933) 25:

J=RTσₑσᵢ/16F²(σₑ+σᵢ)L.In(pₕ/p₁), (1)

wherein R is the gas constant, T the temperature, σₑ and σᵢ the ionic and electronic conductivities, respectively, F the Faraday constant, L the thickness of the membrane and pₕ and p₁ the partial oxygen pressures on the feed and permeate sides, respectively.

### SUMMARY OF THE INVENTION

It is an object of the invention to provide a membrane system for oxygen generation which can be used to generate high oxygen permeation rates.

It is a further object of the invention to provide a method for producing a membrane system for oxygen generation which can be used to generate high oxygen permeation rates.

These objects are achieved by a membrane system comprising a membrane, and a porous substrate for supporting the membrane, wherein the substrate comprises pillars and defined channels for bringing a gas in controlled contact with the membrane.

According to the invention, the substrate is realized with a high porosity by making use of large, well defined and particularly continuous channels, or holes, respectively in the carrier substrate. In other regions of the substrate, i.e. in the region apart from the channels, the substrate may remain as tubes or pillars to fix and hold the membrane and thus to support it. This allows high gas fluxes through the support, or substrate, respectively, and thus through the membrane system as such. In particular, a gas flux, or oxygen flux, respectively from about ≧1 liter per minute or even more may be realized according to the invention. Furthermore, a membrane system according to the invention allows bringing a fluid, in particular air, in controlled contact with the membranes.

The channels and consequently the pillars may have a straight form. However, both the channels as well as the pillars may have any form appropriate, for example arched, branched or any other form, and with a circular or rectangular cross section, for example, as long as a sufficient gas flow through the channels is ensured.

Consequently, the membrane system according to the invention is suitable to form an efficient oxygen generation system allowing high and well defined gas fluxes, and furthermore to achieve also a stable system for handling these especially thin membranes in case the membrane is selectively permeable for oxygen.

Well defined channels, or defined channels, respectively, shall thereby preferably mean that the structure and the size of the channels is shaped, or patterned, respectively according to the required demands. They may thus be arranged and adapted according to desired applications. This allows a gas, in particular air, to be guided to the membrane in a well defined manner. Furthermore, in this way a large contact area of the gas and the membrane can be achieved. The properties of the membrane system, especially with respect to the degree of permeability, or the gas flux, respectively, are thus strong improved. This allows the membrane system according to the invention to be adapted and to be tailor-made to desired applications and requirements. Furthermore, the substrates, the channels, and the membrane systems may be produced in a very reproducible manner.

The membrane system according to the invention and especially the well defined channels can be realized by, for example, applying silicium micro-machining to realize the patterned substrate. But also other technologies such as sandblasting to realize channels in the substrate can be used.

According to the invention, the porosity of the substrate is mainly caused by the defined channels. With this regard, the substrate preferably has a porosity of between 5% and 90%, in particular of between 20% and 80%. This allows a very high gas flux through the membrane system. Additionally, the substrate comprises still enough pillars in a sufficiently large size to avoid the membrane system according to the invention to be instable. Even if the porosity may thereby be formed by the well defined channels mainly, it is furthermore possible to provide a defined porosity inside the substrate next to the defined channels. i.e. in the pillars. This might be formed by the porosity of the substrate material as such, or the porosity of the pillars, respectively.

In a preferred embodiment of the present invention, the channels have a width of ≧30 μm to ≦5 mm, in particular of ≧100 μm to ≦800 μm. This especially allows a high gas flux going through the substrate and thus to the membrane thereby as well allowing nitrogen going back from the membrane in case the membrane system is applied for oxygen generation. Apart from that, the stability of the membrane system is still ensured. With this regard, the width of the channels means its diameter, if the channels are circularly formed.

However, if the channels are formed rectangular, or the like, the width shall mean its wideness, wherein its depth may be bigger or smaller. Preferably, the channels may have the defined width, thereby having a length proceeding through the whole substrate.

In a still further preferred embodiment of the present invention, the substrate has a thickness of ≧50 μm to ≦1 mm, in particular of ≧100 μm to ≦800 μm, especially of ≧100 μm to ≦650 μm. This allows forming the membrane system according to the invention and thus an oxygen generation device, for example, in small dimensions being particularly suitable for portable homecare devices. Additionally, the stability of the membrane system according to the invention is sufficiently high to ensure that the risk of cracks or damages to be formed is minimized.

It is furthermore preferred that the pillars have a width of 50 μm to ≦1 mm, in particular of ≧200 μm to ≦800 mm. This allows the stability of the membrane system to be sufficient, even for very thin membranes and even for portable devices, e.g. in the field of home care applications. The width of the pillars shall thereby mean the distance between respective channels.

In a further preferred embodiment of the present invention, the membrane has a thickness in the range of ≧0.1 μm to ≦40 μm, in particular in the range of ≧0.1 μm to ≦20 μm. This allows the flux of oxygen passing the membrane to be increased as the thickness of the membrane has a major influence to the permeability of the latter. Furthermore, if bulk transport is the major determining step through the membrane, the thinner membranes also open the way to operate the membranes at lower temperatures (see equation 1). As the membrane systems according to the invention can be produced on equipment usually applied for the production of semiconductor devices, low cost productions are possible. Additionally, the membrane system according to the invention can be applied in small, flat devices which are of relevance for applications such as medical applications. Consequently, by forming the membrane in a thickness in a range of 0.1 μm to 40 μm, the permeability ad thus the gas flux of the membrane system may be increased allowing, for example, providing high efficient and small oxygen separation devices.

In a further preferred embodiment of the present invention the substrate is a silicon substrate, a glass substrate, a ceramic substrate such as an aluminum oxide, a glass ceramic substrate, or a metal substrate. These kind of materials exhibit a sufficiently high stability for supporting the membrane, especially if the membrane is formed very thin. Additionally, these materials withstand even high temperatures which might be required to enable a sufficiently high oxygen flux through the membrane. Furthermore, these materials may very well be machined even in micrometer-dimension, i.e. in the dimension of one or more several μm.

In a further preferred embodiment of the present invention, the membrane is based on a perovskite, the perovskite being chosen from the group comprising Sr_{1-y}Ba_{y}Co₁₋ₓFexO_{3-z}, which can undoped or doped with donors or acceptors and La_{1-y}Sr_{y}Fe₁₋ₓCrₓO_{3-z}, which can be undoped or doped with niobium, magnesium, titanium or gallium, Sr_{1-y-x}Ba_{y}LaₓCo_{1-b-c}Fe_{b}Cr_{c}O_{3-z}, which can be undoped or doped with e.g. donors or acceptors like niobium, magnesium, titanium or gallium, Ba₁₋ₓSrₓTiO_{3-z}, which can be undoped or doped with donors or acceptors such as manganese, iron, chromium or any other doping compounds and PbZr₁₋ₓTiₓO_{3-z}, which can be undoped or doped with donors or acceptors such as iron, niobium, lanthanum, chromium any other doping compounds. These kind of ceramic compounds exhibit a good flux of gas and furthermore have an excellent selectivity with respect to oxygen. In detail, if the upstream side of the membrane comprising this component is subjected to an overpressure of air, for example, it will let oxygen pass and thus is a main component of the membrane system to generate oxygen. Thereby, it is possible to generate oxygen in a purity of up to 100%.

In a further preferred embodiment of the present invention, the membrane system further comprises a cover layer on one or both sides of the substrate. With this regard, the cover layer or the cover layers may preferably be formed of silicon oxide, silicon nitride or combinations thereof. Especially an upper cover layer, i.e. a cover layer being located between the substrate and the membrane, may help to fix the membrane to the substrate. It thus improves the stability of the membrane system according to the invention. Additionally, if provided at the side of the substrate being located opposite of the membrane, the cover layer may help forming or shaping, respectively, the channels in the desired manner, thereby acting as a mask, for example. In particular, the cover layer or the cover layers can be dense or porous and can be applied by any deposition technique, for example thermal oxidation or chemical vapor deposition. A silicon nitride layer may be applied by any deposition technique, for example chemical vapor deposition. A glass layer is for example a spin-on glass layer. The thickness of the silicon nitride, or glass layer, respectively is preferably between 100 nm and 100 μm, preferably between 100 nm and 10 μm.

In a further preferred embodiment of the present invention, the membrane system further comprises a barrier layer between the membrane and the cover layer. This barrier layer preferably comprises a material chosen from the group comprising silicon oxide, titanium oxide, magnesium oxide, zirconium oxide, zirconium titanate, aluminum oxide and tantalum oxide, or any combination thereof. The barrier layer can be applied by any deposition method, for example reactive sputtering of oxides, or sputtering of metals followed by thermal oxidation, or spin-on or chemical vapor deposition. It may act as an intermediate layer between the cover layer and the membrane, to prevent reactions between the cover layer and the membrane layer. This could be, for example, reactions of barium oxide in the membrane layer with silicon oxide in the cover. These reactions could result in cracking of the membrane layer.

In a further preferred embodiment of the present invention, a protection layer is arranged on the membrane. This protection layer may for example mechanically protect the membrane and may thus improve the durability of the membrane system according to the invention. The protection layer preferably is formed as an inorganic layer, for example a silicon oxide or silicon nitride layer, but for special processing steps it can also be an organic layer made of photoresist, teflon, parylene. The protection layer can be dense, porous or a layer with holes, in particular having the same width as the channels in the substrate.

It is furthermore preferred that the cover layer, the barrier layer as well as the protection layer may have channels formed in the same width as the substrate. In this way, a good contact of the gases on both sides of the membrane is ensured.

The invention furthermore relates to a method for producing a membrane system according to the invention, wherein the substrate is patterned by silicon micro-machining or sandblasting. In detail, the channels are formed in the above defined way. This ensures the channels to have a defined shape and size and thus enables a gas to come in defined contact to the membrane with a high flux.

In a preferred embodiment of the present invention, a cover layer is applied on at least one side of the substrate. This especially allows improving the stability of the membrane on the substrate. With this regard, it is especially preferred that the cover layer or the cover layers are applied by thermal oxidation, chemical vapor deposition, sputtering, laser ablation or a spin-on process, for example.

In a further preferred embodiment of the present invention, a barrier layer is applied between the cover layer and the membrane. In this way, reactions of the membrane layer with the substrate and the cover layer may be prevented. With this regard, it is especially preferred that the barrier layer is applied by any thin film technology, for example sputtering, laser ablation, chemical vapor deposition or spin-on processing.

### BRIEF DESCRIPTION OF THE DRAWINGS

These and other aspects of the invention will be apparent from and elucidated with reference to the embodiments described hereinafter.

In the drawings:

FIG. 1 shows a schematic sectional side view of one embodiment of a membrane system according to the present invention,

FIG. 2 shows a schematic sectional side view of a further embodiment of a membrane system according to the present invention,

FIG. 3 shows a schematic sectional side view of a further embodiment of a membrane system according to the present invention,

FIG. 4 shows a schematic sectional side view of a further embodiment of a membrane system according to the present invention.

### DETAILED DESCRIPTION OF EMBODIMENTS

In the following, a membrane system 10 according to the invention as well as a method for producing the same is schematically shown. It has to be noted that these embodiments are described exemplarily and in a non-limiting manner and are not limiting the scope of the invention. The respective dimensions are only exemplarily but not limiting. Also combinations of different features according to the embodiments are possible without leaving the invention as such. Additionally, comparable elements are defined by the same numerals.

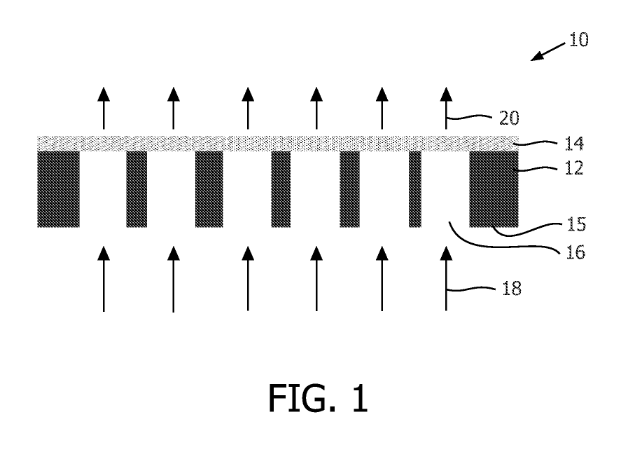

In FIG. 1, the membrane system 10 according to an embodiment of the present invention is schematically shown. The membrane system 10 comprises a substrate 12, which can for example be made of silicon, glass, quartz or aluminum oxide. However, any other substrates 12 such as also a metal substrate may be used. On top of the substrate 12 having a thickness of e.g. 0.2-1 mm, a ceramic membrane 14 having a thickness of e.g. 0.5-40 μm is deposited. According to FIG. 1, the membrane 14 is a ceramic membrane being selectively permeable for oxygen. The ceramic membrane applied may be based on a densely processed polycrystalline inorganic material, which shows a mixed ionic and electronic conductivity and is to a certain extent permeable to oxygen. The oxygen permeability is dependent of several parameters as discussed above. The materials are inorganic materials and in particular oxidic materials from the group of perovskites ABO_{3-z}. Examples of suitable perovskites include Sr_{1-y}Ba_{y}Co₁₋ₓFeₓO_{3-z}, which can be undoped or doped with e.g. donors or acceptors such as lanthanium, La_{1-y}Sr_{y}Fe₁₋ₓCrₓO_{3-z}, which can be undoped or doped with niobium, magnesium, titanium or gallium, Sr_{1-y-x}Ba_{y}LaₓCo_{1-b-c}Fe_{b}Cr_{c}O_{3-z}, which can be undoped or doped with e.g. donors or acceptors like niobium, magnesium, titanium or gallium, Ba₁₋ₓSrₓTiO_{3-z}, which can be undoped or doped with donors or acceptors such as manganese, iron, chromium or any other doping compounds and PbZr₁₋ₓTiₓO_{3-z}, which can be undoped or doped with donors or acceptors such as iron, niobium, lanthanum, chromium any other doping compounds.

In the present embodiment, this can for example be a Sr_{0.5}Ba_{0.5}Co_{0.8}Fe_{0.2}O₃₋ₓ thin film. The deposition can be performed by spin-on processing and annealing to achieve the dense layer. Several spin-on processing steps can be applied. For thick films of e.g. 10-40 μm also technologies such as screen printing can be applied. After deposition of the Sr_{0.5}Ba_{0.5}Co_{0.8}Fe_{0.2}O₃₋ₓ film on the substrate 12, channels 16 are processed from the backside into the substrate 12 by e.g. micromachining of the silicon carrier or by sandblasting of e.g. the glass substrate, thereby leaving pillars 15 in the substrate 12. Due to the fact that the channels 16 are provided by a suitable process, they are well defined and allow a well defined and controlled contact of an air stream, for example, to the membrane 14.

As an alternative, also a porous substrate 12 such as an aluminum oxide substrate can be used as substrate 12. The porosity in such a substrate can be obtained by sintering during preparation of the material, for example. On top of this substrate 12 a ceramic membrane 14 having a thickness of 0.5-3 μm is deposited.

The membrane system 10 according to the invention may be used for example for oxygen generation. It can also be used for other applications such as oxygen generation, removal or control for processing and packaging, aquaculture, small-scale cutting and welding, gas purification, pure oxygen or oxygen-enriched air supply for human consumption, semiconductor manufacturing, or gas calibration for devices such as sensors.

According to FIG. 1, a flow of air 18, for example, is guided to the membrane 14 through the defined channels 16. Due to the oxygen selectivity of the membrane 14, only oxygen will pass the membrane 14 thereby generating an oxygen flow 20.

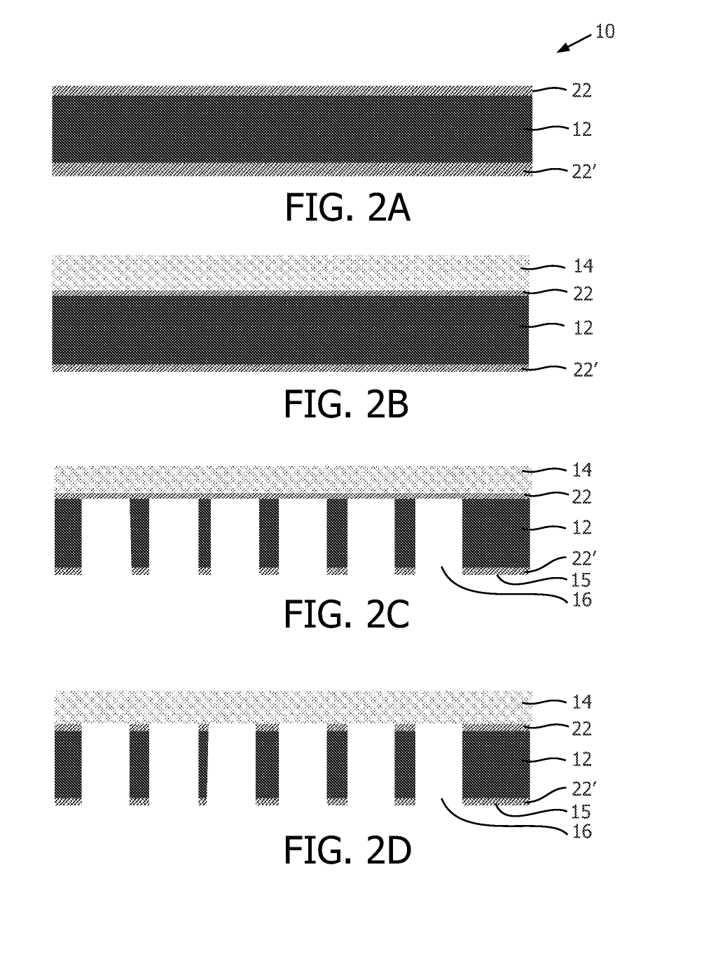

In FIG. 2, a further embodiment of a membrane system 10 according to the invention is schematically shown. In this embodiment, a thin film of a ceramic oxygen membrane 14 on a silicon substrate 12 is produced. The method may be performed as follows: on top of a standard silicon wafer as substrate 12 with a thickness of 0.5-0.7 mm, in particular of 0.5-0.6 mm, a thin silicon oxide layer with a thickness of 0.1-0.5 μm, in particular of 0.1-0.2 μm, which can be dense or porous, is applied by e.g. thermal oxidation as cover layer 22. Also on the back side of the substrate 12, a thin silicon oxide layer as cover layer 22′ is deposited (FIG. 2A). Subsequently, a 0.5-3 μm thick ceramic membrane 14 is deposited (FIG. 2B). In the present embodiment, this can for example be a Sr_{0.5}Ba_{0.5}Co_{0.8}Fe_{0.2}O₃₋ₓ thin film. The deposition can be performed by spin-on processing and annealing to achieve the dense layer. Several spin-on processing steps can be applied. After deposition of the thin Sr_{0.5}Ba_{0.5}Co_{0.8}Fe_{0.2}O₃₋ₓ film on the substrate 12, the silicon oxide layer 22′ on the backside is lithographically patterned. This is followed by dry or wet-etching of the silicium substrate 12 to achieve well defined channels 16 in the substrate 12 (FIG. 2C). In a following step, the cover layer 22 in the openings is etched away (FIG. 2D).

Instead of the standard silicium wafer as substrate 12, also thinned down wafers can be applied as substrate 12 to reduce etching time in a later step.

In a further embodiment the steps as described above are following but instead of the 0.1-0.5 μm, or 0.1-0.2 μm, respectively, thick silicon oxide as cover layer 22, a 0.1-0.5 μm, or 0.1-0.2 μm, respectively, thick silicon nitride layer as cover layer 22 is applied by e.g. chemical vapor deposition. The silicon nitride layer can be a dense or porous layer. Also on the back side of the substrate 12, a thin silicon nitride layer is deposited as cover layer 22′ (FIG. 2A). Subsequently, a 0.5-3 μm thick ceramic membrane material is deposited to form the membrane 14 (FIG. 2B). In the present embodiment, this can for example be a Sr_{0.5}Ba_{0.5}Co_{0.8}Fe_{0.2}O₃₋ₓ thin film. The deposition can be performed by spin-on processing and annealing to achieve the dense layer. Several spin-on processing steps can be applied. After deposition of the thin Sr_{0.5}Ba_{0.5}Co_{0.8}Fe_{0.2}O₃₋ₓ film on the substrate 12, the silicon nitride layer on the backside is lithographically patterned. This is followed by dry or wet-etching of the silicium wafer, or substrate 12, respectively, to achieve well defined channels 16 in the silicium substrate 12 (FIG. 2C). In a following step, the silicon nitride of the cover layer 22 in the channels 16 is etched away (FIG. 2D). Instead of the standard silicium wafer also a thinned down wafer can be applied as substrate 12 to reduce etching time in a later step.

FIG. 2C shows an alternative embodiment, without the cover layer 22 being etched away in the channels 16.

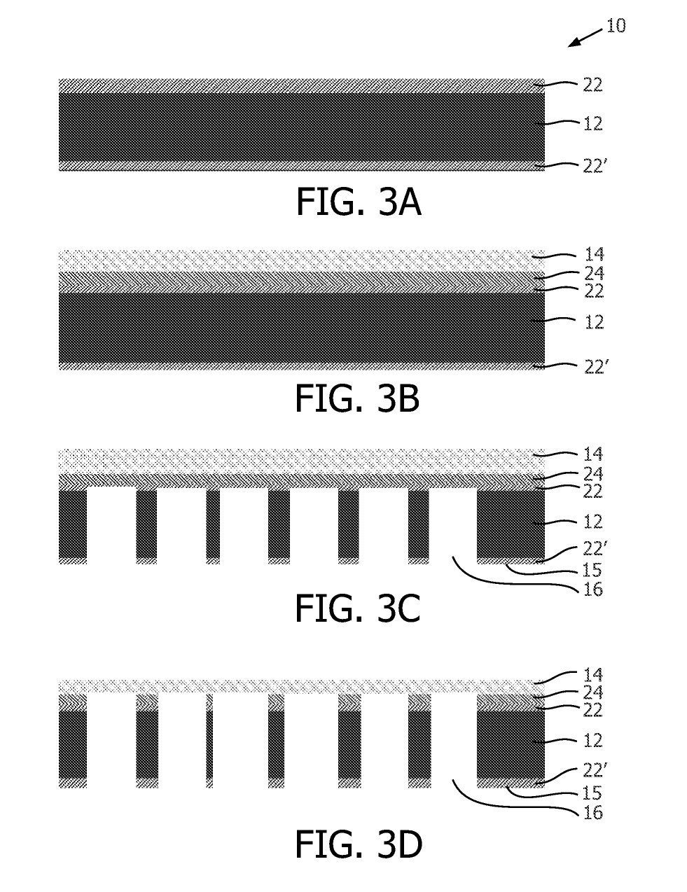

In FIG. 3, an alternative embodiment according to the invention is schematically shown. According to FIG. 3, a thin, for example a 30-500 nm thick layer made of titanium oxide, magnesium oxide, zirconium oxide, zirconium titanate, aluminum oxide, or tantalum oxide, for example, is deposited as a barrier 24 layer on top of the cover layer 22 and thus between the cover layer 22 and a membrane 14 to follow (FIG. 3B). The barrier layer 24 can be dense but preferably is a porous layer. On top of the barrier layer 24, a 0.5-3 μm thick oxygen membrane material is deposited as membrane 14. In the present embodiment this can for example be a Sr_{0.5}Ba_{0.5}Co_{0.8}Fe_{0.2}O₃₋ₓ thin film. The deposition can be performed by spin-on processing and annealing to achieve the dense layer. Several spin-on processing steps can be applied. After deposition of the thin Sr_{0.5}Ba_{0.5}Co_{0.8}Fe_{0.2}O₃₋ₓ film on the substrate 12, the intermediate layer 22′ at the backside is lithographically patterned. This is followed by dry or wet-etching of the substrate 12 to achieve well defined channels 16 in the silicium substrate 12 (FIG. 3C). In a following step the silicon oxide of the cover layer 22 and the barrier layer 24 in the openings are etched away (FIG. 3D). Instead of the standard silicium wafer also a thinned down wafer can be applied to reduce etching time in a later step.

FIG. 3C shows an alternative embodiment, without the cover layer 22 and barrier layer 24 being etched away in the channels 16. In a further embodiment of the present invention, a thin layer, for example having a thickness 30-100 nm, of made of titanium oxide, magnesium oxide, zirconium, zirconium titanate, aluminum oxide, or tantalum oxide, for example, is deposited as a barrier layer 24 between the ceramic membrane 14 and the substrate 12. This barrier layer 24 can be deposited directly on the substrate 12, which can for example be made of glass, quartz or aluminum oxide or glass ceramic or any other substrate such as a metal substrate 12. But also combinations of barrier layers 24 of SiO₂ followed by titanium oxide, magnesium oxide, zirconium oxide, zirconium titanate, aluminum oxide, or tantalum oxide can be applied.

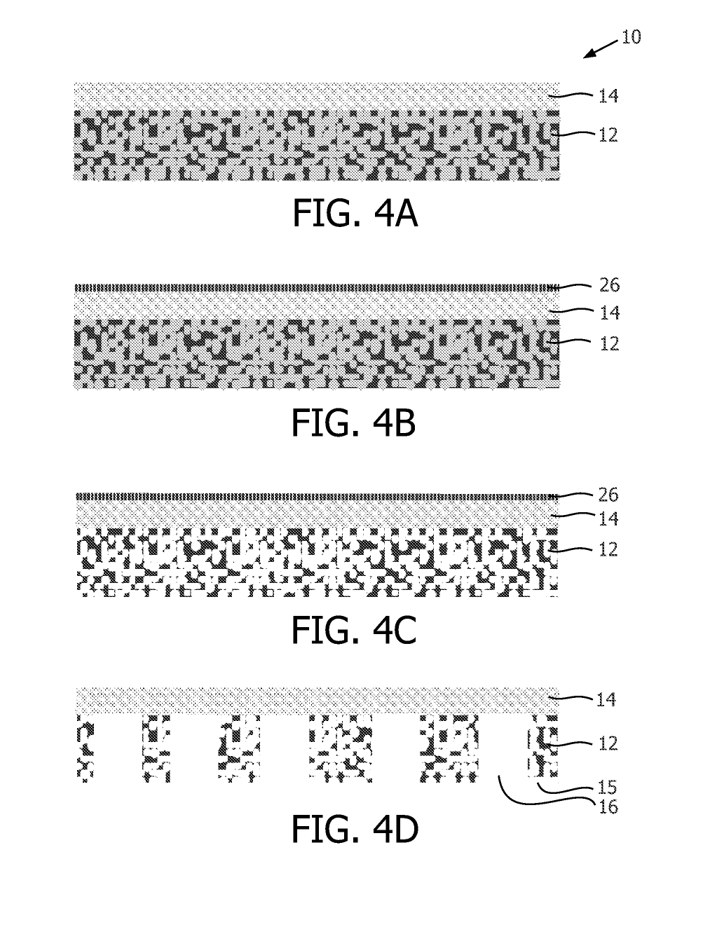

Shown in FIG. 4 is an alternative process to form a membrane system 10 according to the invention. In detail, a substrate 12, composed of two different composite materials is used. Examples could be for example ceramic and metal combinations. On top of this substrate 12 a 0.5-3 μm thick ceramic membrane 14 is deposited as shown in FIG. 4A. After deposition of the ceramic membrane 14, the membrane 14 is covered with a protection layer 26, such as an organic layer, for example photoresist, teflon, or parylene (FIG. 4B). Then the membrane system 10 is applied into an etchant where one of the composite materials of substrate 12 is etched away to achieve a porous carrier, as visualized in FIG. 4C. The materials etched away in the composite could be for example metals such as W, Mo, Cr, which are etched with acids, for example, but could also be metal oxides in the composite, which can be selectively etched with respect to the substrate material. After removal of the protection layer 26, the thin ceramic membrane 14 on top of porous carrier 12 is obtained. The membranes 14 can be used for e.g. gas generation. Additionally, well defined channels 16 are formed into the substrate 12 like described above as shown in FIG. 4D. This embodiment allows a porosity not only being based on the defined channels 6 but also on the porosity of the substrate material as such, or the pillars 15, respectively.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. Membrane system comprising
a membrane (14), and
a porous substrate (12) for supporting the membrane (14), wherein the substrate (12) comprises pillars (15) and defined channels (16) for bringing a gas in controlled contact with the membrane (14).

2. Membrane system according to claim 1, wherein the channels (16) have a width of ≧30 μm to ≦5 mm.

3. Membrane system according to claim 1, wherein the substrate (12) has a thickness of ≧50 μm to ≦1 mm.

4. Membrane system according to claim 1, wherein the pillars (15) have a width of ≧50 μm to ≦1 mm.

5. Membrane system according to claim 1, wherein the membrane (14) has a thickness in the range of ≧0.1 μm to ≦40 μm.

6. Membrane system according to claim 1, wherein the substrate (12) is a silicon substrate, a glass substrate, a ceramic substrate such as an aluminum oxide, a glass ceramic substrate, or a metal substrate.

7. Membrane system according to claim 1, wherein the membrane (14) is based on a perovskite the perovskite being chosen from the group comprising Sr_{1-y}Ba_{y}Co₁₋ₓFexO_{3-z}, which can undoped or doped with donors or acceptors and La_{1-y}Sr_{y}Fe₁₋ₓCrₓO_{3-z}, which can be undoped or doped with niobium, magnesium, titanium or gallium, Sr_{1-y-x}Ba_{y}LaₓCo_{1-b-c}Fe_{b}Cr_{c}O_{3-z}, which can be undoped or doped with e.g. donors or acceptors like niobium, magnesium, titanium or gallium, Ba₁₋ₓSrₓTiO_{3-z}, which can be undoped or doped with donors or acceptors such as manganese, iron, chromium or any other doping compounds and
PbZr₁₋ₓTiₓO_{3-z}, which can be undoped or doped with donors or acceptors such as iron, niobium, lanthanum, chromium any other doping compounds.

8. Membrane system according to claim 1, wherein the membrane system (10) further comprises a cover layer (22, 22′) on one or both sides of the substrate (12).

9. Membrane system according to claim 8, wherein the cover layer (22, 22′) is formed of silicon oxide, silicon nitride, or combinations thereof.

10. Membrane system according to claim 8, wherein the membrane system (10) further comprises a barrier layer (24) between the membrane (14) and the cover layer (22).

11. Membrane system according to claim 10, wherein the barrier layer (24) comprises a material chosen from the group comprising silicon oxide, titanium oxide, magnesium oxide, zirconium oxide, zirconium titanate, aluminum oxide and tantalum oxide, or any combination thereof.

12. Membrane system according to claim 1, wherein a protection layer (26) is arranged on the membrane (14).

13. Method for producing a membrane system (10) according to claim 1, wherein the substrate (12) is patterned by silicon micro-machining or sandblasting.

14. Method according to claim 13, wherein a cover layer (22, 22′) is applied on at least one side of the substrate.

15. Method according to claim 14, wherein a barrier layer (24) is applied between the cover layer (22) and the membrane (14).
